(19) United States
(12) Patent Application Publication
(10) Pub. No.: US 2022/0219971 A1
(43) Pub. Date: Jul. 14, 2022

(54) MULTIPLY ENCAPSULATED MICRO ELECTRICAL MECHANICAL SYSTEMS DEVICE

(71) Applicants: Cambridge Enterprise Limited, Cambridge (GB); Silicon MicroGravity Ltd, Stokenchurch (GB)

(72) Inventors: Ashwin SESHIA, Cambridge (GB); Chun ZHAO, Cambridge (GB); Guillermo SOBREVIELA, Cambridge (GB); Milind PANDIT, Cambridge (GB); Philipp STEINMANN, Cambridge (GB); Arif MUSTAFAZADE, Cambridge (GB)

(21) Appl. No.: 17/607,506

(22) PCT Filed: Apr. 28, 2020
(86) PCT No.: PCT/GB2020/051038

§ 371 Date: Oct. 29, 2021

(30) Foreign Application Priority Data
Apr. 29, 2019 (GB) 1905986.4

(51) Int. Cl. B81B 7/00; B81C 1/00

(52) U.S. Cl. CPC B81B 7/0041; B81C 1/00293; B81B 2201/0271; B81B 2201/0292; B81B 2201/0228; B81B 2201/10

(57) ABSTRACT

There is provided a micro electrical mechanical systems device package comprising: a first vacuum enclosure comprising a first enclosure wall; a micro electrical mechanical systems device being positioned within the first vacuum enclosure on a first side of the first enclosure wall; and a second vacuum enclosure, the second side of the first enclosure wall being within the second vacuum enclosure. Advantageously, the first vacuum enclosure is entirely within the second vacuum enclosure.

### RELATED APPLICATIONS

This application is a U.S. national phase application, claiming priority under 35 U.S.C. § 371 to PCT application PCT/GB2020/051038, filed Apr. 28, 2020, claiming priority to GB Patent Application No. 1905986.4, filed on Apr. 29, 2019. The contents of these applications are incorporated herein by reference in their entireties.

### FIELD OF THE INVENTION

The invention relates to micro electrical mechanical systems (MEMS) devices, and in particular MEMS devices that comprise a vibratory element that vibrates or resonates during operation.

### BACKGROUND

Resonant MEMS devices, typically fabricated from silicon, have developed rapidly over the last few decades. Resonant MEMS devices can be small, inexpensive, have low power consumption and can be batch fabricated. Resonant MEMS devices have been used as inertial sensors, as filters and in timing applications.

However, MEMS resonators are susceptible to drift due to temperature and pressure fluctuations. While a number of approaches have been developed to address temperature dependent effects in MEMS resonant devices, involving both passive and active compensation, pressure related effects have not been adequately addressed. This is a significant issue for mechanically sensitive devices, such as accelerometers and gyroscopes, and particularly gravimeters, where high accuracy is desired. Fluctuations in ambient pressure can induce stresses in the material of the sensor or in the packaging, impacting on sensor accuracy and resolution.

It would be desirable to mitigate the effects of pressure fluctuations on MEMS devices.

### SUMMARY

The invention is defined in the appended independent claims. Preferred features of the invention are set out in the dependent claims.

In a first aspect of the invention, there is provided a micro electrical mechanical systems device package comprising:

a first vacuum enclosure comprising a first enclosure wall;

a micro electrical mechanical systems device being positioned within the first vacuum enclosure on a first side of the first enclosure wall; and

a second vacuum enclosure, the second side of the first enclosure wall being within the second vacuum enclosure.

The micro electrical mechanical systems device package may comprise at least one electrical via extending from a first side of the first enclosure wall within the first vacuum enclosure, through the first enclosure wall to a second side of the first enclosure wall outside of the first vacuum enclosure and within the second vacuum enclosure.

In this context micro electrical mechanical systems (MEMS) is intended to include micro optical electrical mechanical systems (MOEMS).

The device may comprise a vibratory element configured to vibrate, the vibratory element being positioned within the first vacuum enclosure.

The provision of the second vacuum enclosure ensures that variations in a pressure difference between the first and second sides of the first enclosure wall are minimised. This is significant in particular when the first enclosure wall includes an electrical via, because the thickness of the first enclosure wall is then limited. For example, through silicon vias are only readily formed through walls having a thickness of 300 μm or less. Walls of this thickness will flex when there are ambient pressure fluctuations, inducing stresses in the material of the device and so affecting its performance. The first enclosure wall may have a thickness of less than 300 μm.

Minimising the variation in a pressure difference between the first and second sides of the first enclosure wall is particularly desirable when the MEMS device is highly sensitive or is used to provide high resolution measurements.

Advantageously, the first vacuum enclosure is entirely within the second vacuum enclosure.

The pressure in the first vacuum enclosure may be less than 10 mTorr. The pressure in the second vacuum enclosure may be less than 10 mTorr.

The first vacuum enclosure may be formed by wafer level vacuum packaging. Wafer level packaging is a process of packaging that is performed prior to dicing a wafer.

In some embodiments, the first vacuum enclosure may comprise a portion of a cap wafer bonded to the MEMS device wafer. The cap wafer may be formed, for example, from glass, silicon or from a ceramic material. The cap wafer may be bonded to a device wafer, comprising a plurality of MEMS devices. The bonded cap wafer and device wafer may then be diced to form individual packages.

The first enclosure wall may be formed by a portion of the cap wafer or by a portion of the device wafer.

Other wafer level packaging techniques may be used as an alternative, such as packaging using thin film deposition techniques. This includes approaches such as vacuum encapsulation using epitaxial polysilicon, permeable polysilicon, electro-deposited metal or other relevant approaches.

The second vacuum enclosure may be formed by die level packaging. Die level packaging is formed after a wafer has been diced into individual devices. The die level packaging of the second enclosure may be formed from a ceramic chip carrier and a lid. The lid may be formed from glass or another ceramic material. The ceramic chip carrier may be formed from alumina. The lid may be sealed to the chip carrier using an adhesive or by brazing for example. The first vacuum enclosure may be fixed to the chip carrier using an adhesive, such as a low stress glue. A spacer element may be positioned between the chip carrier and the first vacuum enclosure. The spacer element may reduce temperature sensitivity of the device. The spacer element may be formed from aluminium nitride for example. The first vacuum enclosure may be fixed to the spacer and the spacer may be fixed to the chip carrier.

The device package may comprise wire bonds, electrically connecting the device in the first vacuum enclosure to electrical or optical vias formed through the second vacuum package.

The second vacuum enclosure may be formed by wafer level packaging. A second vacuum enclosure may comprise one or more secondary wafers fixed to the first vacuum enclosure.

One or more vias may be formed through a secondary wafer to allow for electrical or optical connection of the MEMS device to external circuitry.

The MEMS device may be, for example, an inertial sensor, a timing device or a filter. The MEMS device may be a gravimeter. The vibratory element may be a resonator. The MEMS device may be a resonant sensor. Electrical and/or optical interfacing may be integrated through the first and/or second vacuum enclosure for transduction of the vibratory element.

The device package may comprise one or more getters within the first vacuum enclosure or the second vacuum enclosure. A getter may be provided in each of the vacuum enclosures.

The device package may further comprise a third vacuum enclosure, the second vacuum enclosure being within the third vacuum enclosure. The provision of a third vacuum enclosure may further reduce the effect of variations in the ambient pressure on the output of the MEMS device

The MEMS device may comprise a second vibratory element coupled to the first vibratory element. With such an arrangement the phenomenon of mode localisation may be exploited to provide highly accurate sensing devices. A change in the resonant frequency of one of the vibratory elements compared to the other of the vibratory elements can result in a change in the eigenstates of the coupled vibratory elements. An example of this type of device is described in WO2011/148137.

In a second aspect of the invention, there is provided a method of manufacturing a micro electrical mechanical systems device package comprising a micro electrical mechanical systems device, the method comprising:

vacuum packaging the device in a first vacuum package; and

vacuum packaging at least a portion of the first package in a second vacuum package.

The portion of the first package may comprise an enclosure wall comprising one or more electrical or optical vias formed through it. The device may comprise a vibratory element configured to vibrate.

The step of vacuum packaging at least a portion of the first vacuum package in a second vacuum package may comprise vacuum packaging the entire first vacuum package in the second vacuum package. The second vacuum package may enclose the first vacuum package.

The step of vacuum packaging the device in a first package may comprise wafer level packaging.

The step of vacuum packaging at least a portion of the first package in a second package may comprise die level packaging of the first package.

The method may further comprise vacuum packaging at least a portion of the second vacuum package in a third vacuum package.

Features described in relation to the first aspect of the invention may be applied to the second aspect of the invention.

### BRIEF DESCRIPTION OF THE DRAWINGS

Embodiments of the invention will now be described in detail, by way of example only, with reference to the accompanying drawings, in which:

FIG. 1 illustrates an example of a topology for a MEMS device comprising a resonant element;

FIG. 2 illustrates wafer level packaging for a MEMS device;

FIG. 3 illustrates a first embodiment of the invention;

FIG. 4a illustrates a second embodiment of the invention;

FIG. 4b illustrates a third embodiment of the invention;

FIG. 5 illustrates a fourth embodiment of the invention; and

FIG. 6 illustrates a fifth embodiment of the invention.

### DETAILED DESCRIPTION

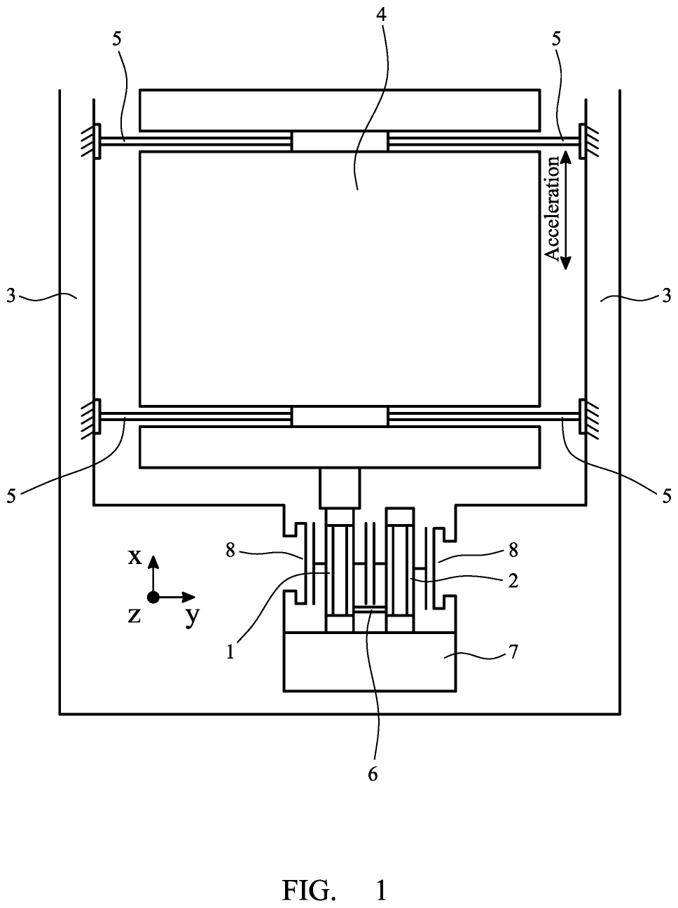

FIG. 1 illustrates a MEMS inertial sensor that includes a resonant element, and that requires vacuum packaging for optimal operation. The sensor comprises two resonant elements 1, 2, which in this example are double ended tuning forks (DETFs). The two resonant elements 1, 2 are adjacent to one another and are integrally formed with a substrate or frame 3. The first resonant element 1 is integrally attached to a proof mass 4, which is suspended from the frame by flexures 5. The two resonant elements are weakly coupled by a mechanical coupling element 6.

The resonant elements can be made to resonate using several different alternative techniques. In a preferred embodiment the resonant elements are made to resonate using an electrostatic technique, by the application of an alternating voltage to a drive electrode 7 on the frame 3, at the base of the resonant elements, and the provision of another drive electrode 8 adjacent the resonant elements.

The mechanical coupling is located towards the base of the resonant elements, i.e. close to the frame 3. The reason for this is that the potential energy contribution is largest near the base of the resonant elements, so that the mechanical coupling in that position mimics the behaviour of a spring without adding any additional mass to the system. So the mechanical coupling under such conditions can be modelled as a spring alone.

Strain modulation on the first resonant element 1 applied by the accelerating proof mass 4 in the drive direction modifies the effective stiffness of the first resonant element 1. This leads to a localisation of the vibration mode in one or other of the resonating elements 1, 2. The amplitude of vibration of each of the resonating elements is measured by capacitive transduction using electrode 8 and the amplitude ratio calculated to provide an output indicative of the acceleration on the proof mass. Alternatively, the amplitude of vibration on one resonant element may be controlled to be constant, using a feedback control loop, and the amplitude of vibration of the other resonant element used as the output indicative of acceleration of the proof mass. In order to measure the amplitude of vibration several different techniques may be used such as optical or electromagnetic measurement. However, in this embodiment sense electrodes 8 are provided for capacitive sensing.

The sensor of FIG. 1 is advantageously fabricated entirely from a single semiconductor wafer, such as a silicon-on-insulator (SOI) wafer and can be fabricated using conventional MEMS fabrication techniques, such as etching. This includes the frame 3, the resonant elements 1, 2, the proof mass 4, and the flexures 5. To minimize damping of the resonant elements, the sensor is vacuum packaged, as will be described.

The sensor of FIG. 1 relies on mode localization to measure acceleration. Mode localization in a device of this type may be illustrated by considering the simple case of two weakly coupled resonant elements with masses m₁ and m₂ and stiffnesses k₁ and k₂. One of the resonant elements is connected to a proof mass. When the two resonant elements are perfectly identical (m₁=m₂=m; k₁=k₂=k) the system is symmetric about the coupling, which has a stiffness k_{c}. The relative shift in the eigenstates due to a strain modulated change in stiffness on the resonant element connected to the proof mass of (Δk) is given by:

$$\frac{Δ u}{{u}^{0}} ≅ \frac{Δ k}{4 {k}_{c}} . \qquad ( 1 )$$

This critical dependence of parametric sensitivity on the strength of internal coupling (k_{c}) can be exploited to provide very high resolution acceleration measurements. Furthermore, since the eigenstates are deduced from the amplitudes of vibration of both the coupled resonators at the eigenvalues, any effects on the stiffness due to ambient environmental fluctuations (e.g. temperature) affect both the identical resonators to the same extent, thereby leading to a common mode cancellation of these effects to the first order. However, any changes in the stiffness on one of the resonators relative to the other (differential mode), leads to significant shifts in the eigenstates under conditions of weak internal coupling as expressed in equation (1). Such a common mode rejection capability enables the realization of inertial sensors that are orders of magnitude more sensitive to the measurand alone without employing any active/passive control or compensation techniques, making this form of sensing particularly attractive over the more conventional resonant frequency based sensing approach. A device of the type shown in FIG. 1 is described in more detail in WO2011/148137.

However, fluctuations in the ambient pressure can affect the frequency response of the resonators to different degrees. To understand this, it is necessary to understand how the devices are typically vacuum packaged.

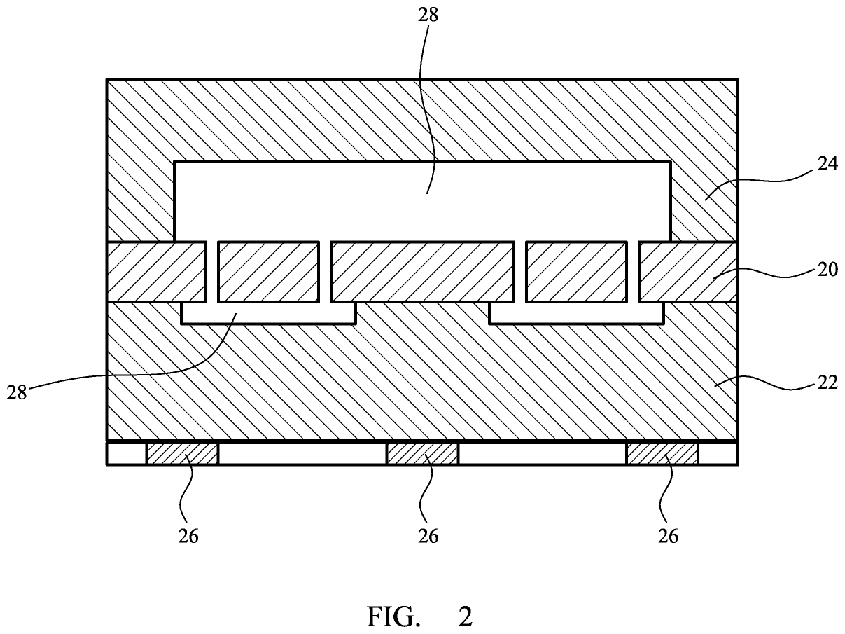

FIG. 2 illustrates a cross section of a wafer level packaged MEMS device of the type illustrated in FIG. 1. Wafer level packaging is typically preferred to die level packaging because with die level packaging the quality of the vacuum is lower and leakage is a more significant problem. Wafer level packaging also allows for simpler batch processing when large volumes of devices are to be produced.

The device layer 20, which is a portion of a wafer, is enclosed by a via wafer 22 and a cap wafer 24. Electrical vias (not shown) are provided through the via wafer 22. Contact pads 26 are provided to allow for electrical connection to the sensor device. A vacuum cavity 28 is formed between the via wafer 22 and the cap wafer 24, in which the sensor, and in particular the resonant elements, are positioned. The vacuum may be provided by the use of one or more getters in the cavity 28.

The cap wafer and via wafer can be bonded to the device layer wafer to provide a hermetically sealed package using a number of established methods, such as anodic bonding, metal bonding, plasma-activated bonding, boding using intermediate melting materials, soldering or eutectic bonding.

The cap wafer and the via wafer are typically quite thin, being less than 50 μm thick. As a result, the pressure difference between the vacuum cavity 28 and the ambient environment will cause the cap wafer and/or the via wafer to flex and lead to a stress in the wafers that is directly transferred into the device layer. Since the stress will not be equally distributed, there may be a mismatch in the effect the stress has on the two resonant elements.

This stress may lead to drift in the resonant frequencies of the resonant elements over time and may also result in short term fluctuations if the ambient pressure fluctuates. Although using thicker via and cap wafers would mitigate this effect, the thickness of the via wafer in particular is limited. It is not possible to form small vias for electrical or optical connection in wafers more than around 300 μm thick.

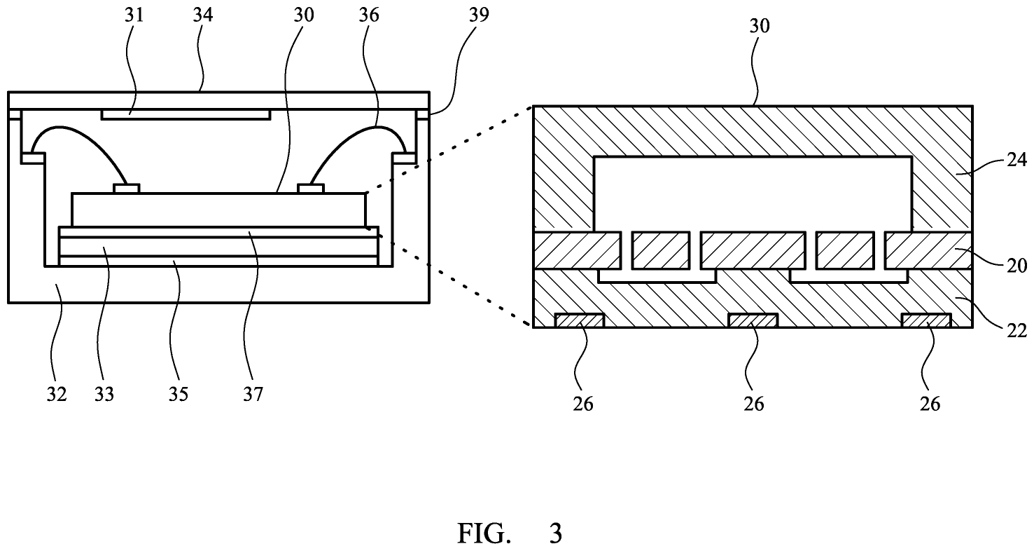

FIG. 3 illustrates a first embodiment of the invention. In the embodiment of FIG. 3 a wafer level packaged MEMS sensor 30, as shown in FIG. 2, is itself held within a second vacuum package. In the embodiment of FIG. 3, the second vacuum package is a die level package.

The wafer level package of FIG. 2 is shown on the right-hand side of FIG. 3, and is shown as element 30 on the left-hand side of FIG. 3. The wafer level package 30 is held within an alumina chip carrier 32. An aluminium nitride spacer element 33 is positioned between the chip carrier 32 and the wafer level package 30. Low stress glue layers 35 and 37 are used to fix the spacer 33 to the chip carrier 32 and the wafer level package 30 to the spacer 33, respectively. A solder preform 39 is applied to a top surface of the chip carrier. A glass lid 34 with a metal seal frame is brazed to the chip carrier 32. A getter 31 may be provided on the underside of the lid to ensure a high vacuum is achieved. Wire bonds are used to provide an electrical connection between the contact pads on the first package and vias (not shown) formed through the chip carrier.

With this arrangement, the pressure differential across the enclosure walls of the first package is very small and the amount of stress transferred to the device layer resulting from changes in ambient pressure is much reduced compared to when only a single wafer level package is used.

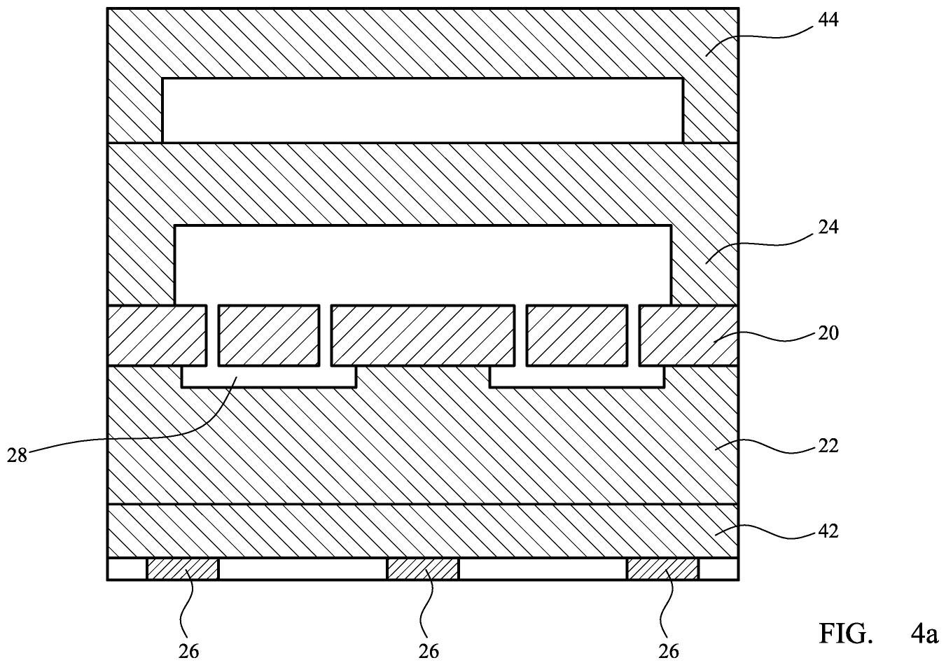

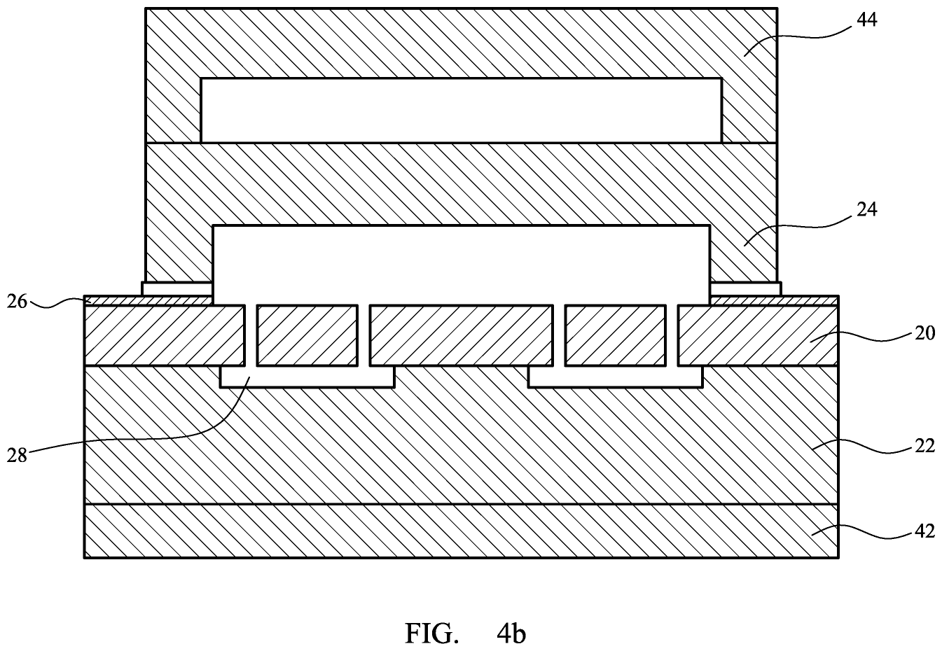

FIG. 4a illustrates a second embodiment of the invention. The second embodiment the second vacuum enclosure is formed by wafer level packaging. In FIG. 4 the MEMS device layer 20 is encapsulated in a first wafer level package comprising a via wafer layer 22 and a cap wafer layer 24, as illustrated in FIG. 2. A secondary encapsulation is provided by a a second cap wafer layer 44. Wafer layer 42 is bonded to wafer layer 22 to reduce the pressure sensitivity. Electrical connections are made through both via wafer layers 22 and 42. Contact pads 46 are provided on the second via wafer layer 42, for connecting the MEMS device to external electrical circuitry.

FIG. 4b illustrates a further embodiment, similar to FIG. 4a, but in which the electrical feedthroughs 26 are drawn from underneath the cap wafer layer 24 rather than through the via wafer layers.

It is possible to add further layers of vacuum packaging to further reduce the effect of ambient pressure variations on the output of the device. For example, the double vacuum encapsulated package of FIG. 4 can replace the single wafer level encapsulated package 30 of FIG. 3 to form a triple vacuum encapsulated package. Two wafer level packages would be held within a die level package.

It is also possible to place a die level packaged device within another die level package. However, this would be relatively bulky.

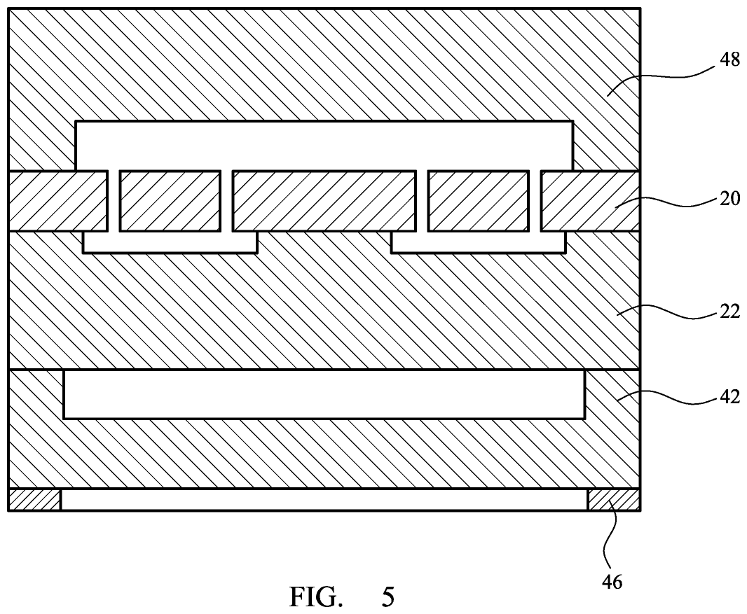

FIG. 5 illustrates a third embodiment of the invention, in which a first vacuum package is only partially encapsulated by a second package. The via wafer 22 forms a first enclosure wall which is encapsulated by a second via wafer 42 with electrical feedthroughs drawn through both via wafers. However, the cap wafer layer 48 is made thicker than in the embodiments of FIGS. 4a and 4b. The thick cap wafer layer 48 is not further encapsulated. The relatively thicker wall of the cap wafer layer 48 means lower stress is transferred through the cap wafer layer to the device layer as a result of ambient pressure variations and so a large and varying pressure differential across the cap layer may not significantly impact on the device performance.

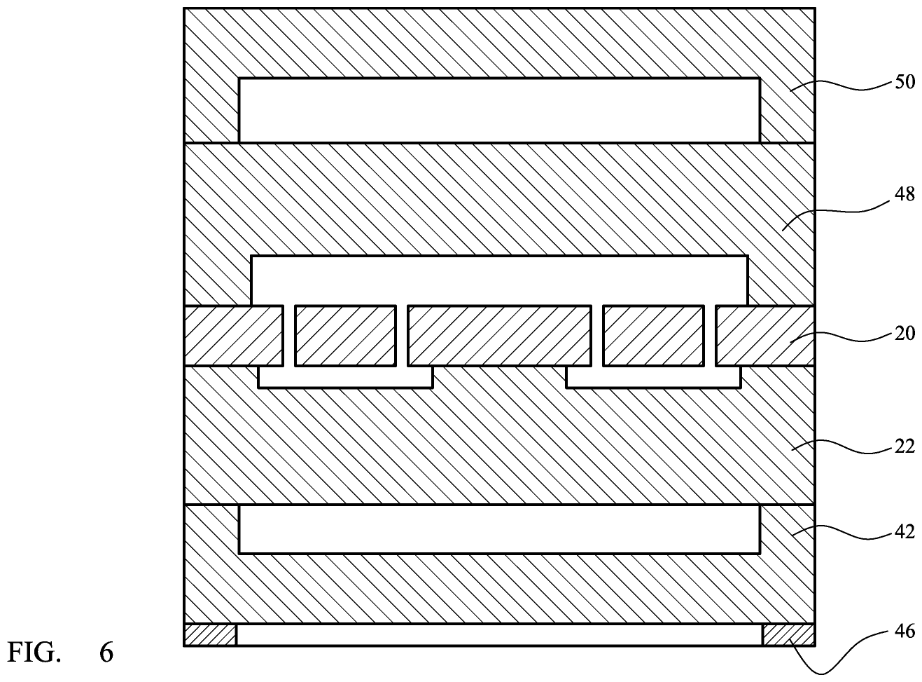

FIG. 6 illustrates a further embodiment of the invention, similar to the embodiment of FIG. 5, but in which a further vacuum seal is provided on the top of the first level cap wafer layer 48 by a further cap wafer layer 50.

The multiple level vacuum packaging schemes described allow the noise floor of resonant MEMS devices to be significantly reduced and allows for improvement in the noise stability of the device too. Thus higher resolution MEMS devices can be practically realised.

Although the invention has been described in relation to a MEMS accelerometer exploiting mode localisation, it should be clear that the same packaging techniques can be applied to any high sensitive resonant MEMS or MOEMS devices. For example, double or triple vacuum packaging can be beneficial for high sensitive MEMS strain gauges and for high resolution timing devices.

1. A micro electrical mechanical systems device package comprising:
a first vacuum enclosure;
a micro electrical mechanical systems device positioned within the first vacuum enclosure; and
a second vacuum enclosure, wherein the first vacuum enclosure is entirely within the second vacuum enclosure.

2. A micro electrical mechanical systems device package according to claim 1, wherein the first vacuum enclosure comprises a first enclosure wall, the micro electrical mechanical systems device positioned on a first side of the first enclosure wall, the second side of the first enclosure wall being within the second vacuum enclosure.

3. A micro electrical mechanical systems device package according to claim 2, comprising at least one electrical via extending from a first side of the first enclosure wall within the first vacuum enclosure, through the first enclosure wall to a second side of the first enclosure wall outside of the first vacuum enclosure.

4. A micro electrical mechanical systems device package according to claim 2 or 3, wherein electrical and/or optical interfacing is integrated through the first enclosure wall for transduction of the resonant element.

5. A micro electrical mechanical systems device package according to claim 4, wherein at least one through silicon via is formed through the first enclosure wall.

6. A micro electrical mechanical systems device package according to any one of the claims 2 to 5, wherein the first enclosure wall has a thickness of less than 300 μm.

7. A micro electrical mechanical systems device package according to any one of the preceding claims, wherein the pressure in the first vacuum enclosure is less than 10 mTorr.

8. A micro electrical mechanical systems device package according to any one of the preceding claims, wherein the first vacuum enclosure is formed by wafer level vacuum packaging.

9. A micro electrical mechanical systems device package according to any one of the preceding claims, wherein the second vacuum enclosure is formed by die level packaging.

10. A micro electrical mechanical systems device package according to any one of the preceding claims, wherein the device is an inertial sensor, timing device or filter.

11. A micro electrical mechanical systems device package according to any one of the preceding claims, wherein the device is a gravimeter.

12. A micro electrical mechanical systems device package according to any one of the preceding claims, wherein the device comprises a vibratory element configured to vibrate, the vibratory element being positioned within the first vacuum enclosure.

13. A micro electrical mechanical systems device package according to claim 12, wherein the vibratory element is a resonator.

14. A micro electrical mechanical systems device package according to claim 12 or 13, further comprising a second vibratory element coupled to the first vibratory element.

15. A micro electrical mechanical systems device package according to any one of the preceding claims, wherein the device is a resonant sensor.

16. A micro electrical mechanical systems device package according to any one of the preceding claims, comprising a getter within the first vacuum enclosure and/or the second vacuum enclosure.

17. A micro electrical mechanical systems device package according to any one of the preceding claims, further comprising third vacuum enclosure, the second vacuum enclosure being within the third vacuum enclosure.

18. A method of manufacturing a micro electrical mechanical systems device package, the method comprising:
vacuum packaging the device in a first package; and
vacuum packaging at least a portion of, and preferably all of, the first package in a second package.

19. A method according to claim 18, wherein the step of vacuum packaging the device in a first package comprises wafer level packaging.

20. A method according to claim 18 or 19, wherein the step of vacuum packaging at least a portion of the first package in a second package comprises die level packaging of the first package.
